(19) United States
(12) Patent Application Publication
(10) Pub. No.: US 2026/0188366 A1
(43) Pub. Date: Jul. 2, 2026

(54) Asymmetric Clock Gating Scheme

(71) Applicant: Micron Technology, Inc., Boise, ID (US)

(72) Inventor: Brynan Qiu, Dallas, TX (US)

(21) Appl. No.: 19/389,954

(22) Filed: Nov. 14, 2025

Related U.S. Application Data
(60) Provisional application No. 63/740,617, filed on Dec. 31, 2024.

(51) Int. Cl. G11C 7/22; G11C 7/10

(52) U.S. Cl. CPC G11C 7/222; G11C 7/1063; G11C 7/1066

(57) ABSTRACT

A memory device includes command path circuitry and clock gating and generation circuitry. The command path circuitry includes shifting circuitry that may shift a command signal and that may include one or more final shifters. The clock gating and generation circuitry may generate a first set of phase-shifted clock signals, transmit the first set of phase shifted clock signals to the shifting circuitry, receive one or more busy signals from the shifting circuitry, determine, based on the one or more busy signals, that the one or more final shifters are storing the command signal, generate, based on the determination, a second set of phase-shifted clock signals.

### CROSS-REFERENCE TO RELATED APPLICATION

This application claims priority to U.S. Provisional Application No. 63/740,617, filed Dec. 31, 2024, which is incorporated by reference herein in its entirety.

### BACKGROUND OF THE INVENTION

### 1. Field Of The Invention

The present invention relates generally to semiconductor devices. More specifically, embodiments of the present disclosure relate to clock gating for signals.

### 2. Description Of The Related Art

A semiconductor device, such as a microcomputer, memory, gate array, among others, may include command paths to transmit commands from a command source, such as an input pin, register, controller, and the like, to logic in the semiconductor device configured to implement the command. The command paths may include digital circuits that may be used in the semiconductor device to facilitate implementing the command. In such a digital logic circuit, command data or signals are stored in memory elements, such as flip-flops, and changes in the states (e.g., toggling) of the memory elements are synchronized by a clock gating cell with logic gate(s) to generate a clock signal. For example, the output of a flip-flop is constant until a pulse is applied to its clock input, upon which the data at the input of the flip-flop is latched to its output.

Additionally, to account for functions of the semiconductor device that operate according to different clocking mechanisms, the clock signal may be phase-shifted by various degrees, and the phase-shifted clocks signals may be applied to the flip-flops at various points in the command path. However, maintaining and applying multiple clock signals for each clocking and switching event of the flip-flops may consume power. Accordingly, embodiments of the present disclosure may be directed to selectively providing such clock signals.

### BRIEF DESCRIPTION OF THE DRAWINGS

FIG. 1 is a simplified block diagram illustrating certain features of a memory device, in accordance with an embodiment;

FIG. 2 is a block diagram of command path circuitry in a command decoder of the memory device of FIG. 1, in accordance with an embodiment;

FIG. 3 is a block diagram of clock gating circuitry of the command path circuitry of FIG. 2 that generates an enable signal for one or more clock signals, in accordance with an embodiment;

FIG. 4 is a block diagram of clock generation circuitry of the command path circuitry of FIG. 2 that selectively generates one or more clock signals based on an enable signal, in accordance with an embodiment;

FIG. 5 is a timing diagram that includes waveforms of signals of the command path circuitry of FIG. 2, in accordance with an embodiment; and

FIG. 6 is a flow chart of a method for selectively providing one or more clock signals, in accordance with an embodiment.

### DETAILED DESCRIPTION OF SPECIFIC EMBODIMENTS

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

As mentioned, a semiconductor device, such as a microcomputer, memory, gate array, among others, may include command paths to transmit commands from a command source, such as an input pin, register, controller, and the like, to logic in the semiconductor device configured to implement the command. The command paths may include synchronous digital circuits that may be used in the semiconductor device to facilitate implementing the command. In a synchronous digital logic circuit, command data or signals are stored in memory elements, such as flip-flops, and changes in the states (e.g., toggling) of the memory elements are synchronized by a clock gating cell with logic gate(s) to generate a clock signal. For example, the output of a flip-flop is constant until a pulse is applied to its clock input, upon which the data at the input of the flip-flop is latched to its output.

Some command paths may include multiple shifter stages, each stage including multiple flip-flops that are chained together by connecting the output of one flip-flop to the input of another. Such a cascade of flip-flops may together form a shift register, in which a command signal may be stored in, and shifted between, the multiple flip-flops of the multiple stages. The multiple stages may be synchronized according to various clock signals to account for various functions of the semiconductor device. For example, a first one or more stages may be synchronized according to an unshifted clock signal and 180-degree phase-shifted clock signal, and a second one or more stages may be synchronized according to a 90-degree phase-shifted clock signal and a 270-degree phase shifted clock signal. However, generating phase-shifted versions of the clock signal may consume power, and certain phase-shifted clock signals may not be used by the shifter stages for substantial portions of the command path. It may thus be advantageous to selectively generate and/or provide the phase-shifted clock signals to reduce power consumption.

Systems and methods described herein include clock gating and/or generation circuitry that selectively generates clock signals that may be provided to stages of a command path that carries a command signal. Each stage may include shifter circuity, such as flip-flops that are synchronized according to a clock signal. The clock gating and/or generation circuitry may enable a first set of clock signals to be provided to the first stages of the command path that use the first set of clock signals. The clock gating and/or generation circuitry may receive busy signals that indicate whether one or more of the first stages of the command path are in use (e.g., storing and latching a command signal). Based on the busy signals, the clock gating and/or generation circuitry may enable a second set of clock signals to be provided to one or more second stages (e.g., an exit stage) of the command path that use the second set of clock signals. The second stages of the command path may be arranged such that they receive the command signal after the first stages (e.g., from the first stages). As such, if the busy signals indicate that the latter stages of the first stages are storing the command signal, the clock gating and/or generation circuitry may enable the second clock signals prior to operation of the second stages.

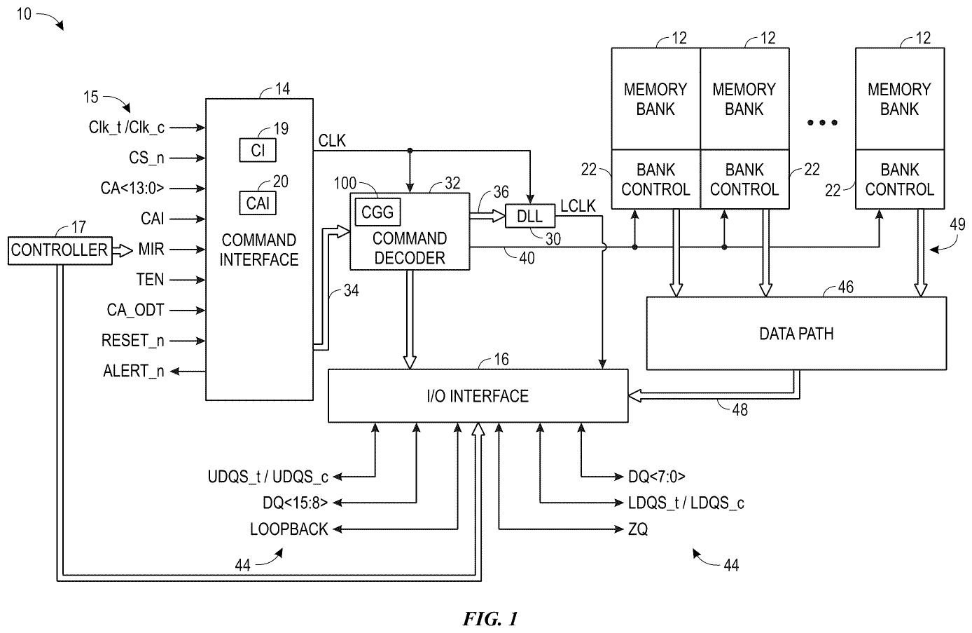

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a DDR5 SDRAM device. Various features of DDR5 SDRAM allow for reduced power consumption, more bandwidth and more storage capacity compared to prior generations of DDR SDRAM.

The memory device 10, may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabyte (Gb) DDR5 SDRAM, the memory chip may include 16 memory banks 12, arranged into 8 bank groups, each bank group including 2 memory banks. For a 16 Gb DDR5 SDRAM, the memory chip may include 32 memory banks 12, arranged into 8 bank groups, each bank group including 4 memory banks, for instance. Various other configurations, organizations, and sizes of the memory banks 12 on the memory device 10 may be utilized depending on the application and design of the overall system.

The memory device 10 may include a command interface 14 and an input/output (I/O) interface 16. The command interface 14 is configured to provide a number of signals (e.g., signals 15) from an external device, such as a processor or controller 17. The processor or controller 17 may provide various signals 15 (including the DQ signals) to the memory device 10 to facilitate the transmission and receipt of data to be written to or read from the memory device 10.

As will be appreciated, the command interface 14 may include a number of circuits, such as a clock input circuit 19 and a command address input circuit 20, for instance, to ensure proper handling of the signals 15. The command interface 14 may receive one or more clock signals from an external device. Generally, double data rate (DDR) memory utilizes a differential pair of system clock signals, referred to herein as the true clock signal (Clk_t) and the bar clock signal (Clk_c). The positive clock edge for DDR refers to the point where the rising true clock signal Clk_t crosses the falling bar clock signal Clk_c, while the negative clock edge indicates that transition of the falling true clock signal Clk_t and the rising of the bar clock signal Clk_c. Commands (e.g., read command, write command, etc.) are typically entered on the positive edges of the clock signal and data is transmitted or received on both the positive and negative clock edges.

The clock input circuit 19 receives the true clock signal (Clk_t) and the bar clock signal (Clk_c) and generates an internal clock signal CLK. The internal clock signal CLK is supplied to an internal clock generator, such as a delay locked loop (DLL) circuit 30. The DLL circuit 30 generates a phase controlled internal clock signal LCLK based on the received internal clock signal CLK. The phase controlled internal clock signal LCLK is supplied to the I/O interface 16, for instance, and is used as a timing signal for determining an output timing of read data.

The internal clock signal(s)/phases CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For instance, the command decoder 32 may provide command signals to the DLL circuit 30 over the bus 36 to coordinate generation of the phase controlled internal clock signal LCLK. The phase controlled internal clock signal LCLK may be used to clock data through the IO interface 16, for instance. As will be appreciated, the command decoder 32 may include components, such as command path circuitry 33 coupled to the command bus 34 to facilitate the flow of signals and/or logical operations performed on those signals.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes a bank control block 22 which provides the necessary decoding (e.g., row decoder and column decoder), as well as other features, such as timing control and data control, to facilitate the execution of commands to and from the memory banks 12.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20 which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the IO interface 16. More specifically, the data may be sent to or retrieved from the memory banks 12 over the datapath 46, which includes multiple bi-directional data buses. Data IO signals, generally referred to as DQ signals, are generally transmitted and received in one or more bi-directional data buses. The datapath 46 may convert the DQ signals from a serial bus 48 to a parallel bus 49.

For certain memory devices, such as a DDR5 SDRAM memory device, the IO signals may be divided into upper and lower bytes. For instance, for a x16 memory device, the IO signals may be divided into upper and lower IO signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the DQS signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance.

The DQS signals are driven by the controller 17 to the memory device 10 to strobe in write data. When the write operation is complete, the controller 17 will stop driving the DQS and allow it to float to an indeterminate tri-state condition. When the DQS signal is no longer driven by the controller 17, the external DQS signal from the controller 17 to the memory device 10 will be at an unknown/indeterminate state. This state can cause undesirable behavior inside the memory device 10 because an internal DQS signal inside the memory device 10 may be at an intermediate level and/or may oscillate. In some embodiments, even the external DQS signal may ring at the I/O interface 16 when the controller 17 stops driving the external DQS signal.

The DDR5 specification may include a short postamble period where the external DQS signal is still driven by the controller 17 after the last write data bit to allow time for disabling of write circuitry to propagate before the controller 17 ceases to drive the external DQS signal. The DDR5 specification may define a short (e.g., 0.5 tCK) postamble period and a long (e.g., 1.5 tCK) postamble period that may be selected using a mode register. However, the short postamble period may provide a short period of time to reset a DFE buffer.

Returning to FIG. 1, an impedance (ZQ) calibration signal may also be provided to the memory device 10 through the IO interface 16. The ZQ calibration signal may be provided to a reference pin and used to tune output drivers and ODT values by adjusting pull-up and pull-down resistors of the memory device 10 across changes in process, voltage, and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback signal (LOOPBACK) may be provided to the memory device 10 through the IO interface 16. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the IO interface 16.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory device 10. Accordingly, it should be understood that the block diagram of FIG. 1 is only provided to highlight certain functional features of the memory device 10 to aid in the subsequent detailed description.

DDR5 allows write operations to be performed consecutively such that data entry is gapless between two consecutive writes. In this case, the normal postamble for the first write operation and/or the normal preamble for the second write operation may be completely eliminated. For some consecutive write operations, there may be cycle gaps having a certain gap (e.g., 1, 2, 3, or more cycles) between the data burst of the first write operation and the data burst of the second write operation. For these cases, there may be a specified partial postamble and/or partial preamble to support these operations.

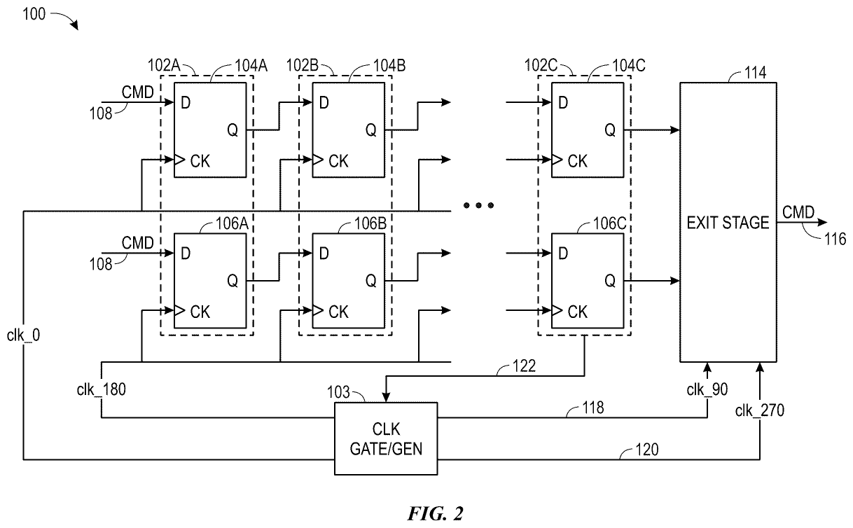

As set forth above, the command decoder 32 may include components, such as command path circuitry 100 coupled to the command bus 34 to facilitate the flow of signals and/or logical operations performed on those signals. FIG. 2 is an example block diagram of the command path circuitry 100 that carries a command signal 108. The command signal 108 may indicate a command for a memory device, such as a read command or write command. In some cases, the command signal 108 may correspond to an on-die termination command. The command path circuitry 100 may include numerous shifting stages (e.g., 60 or more shifting stages), here illustrated as shifting stages 102A, 102B, and 102C (collectively, “shifting stages 102”). Additionally, the command path circuitry 100 may include an exit stage 114, also referred to herein as exit stage circuitry 114. The command path circuitry 100 may also include clock gating and generation circuitry 103 that provides clock signals to the shifting stages 102 and the exit stage 114. The clock gating and generation circuitry 103 may represent, include, and/or be part of part of the circuitry of the memory device 10. For example, the clock gating and generation circuitry 103 may be part of the DLL circuit 30 of FIG. 1. Further, while an example of the command path circuitry 100 is shown for illustrative purposes as a single shifter with two paths, the command path circuitry 100 of the present embodiments may include additional paths for command signals, additional shifting stages, and/or additional exit stages, and the clock gating and generation circuitry 103 may selectively provide clock signals to those additional components.

Each of the shifting stages 102 may include one or more flip-flops that store and latch the command signal 108 based on a clk_0 signal or a clk_180 signal that each correspond to alternating clock cycles (e.g., odds and evens) of the clk. In the illustrated example, the shifting stages 102 respectively include a flip-flop 104A, a flip-flop 104B, and a flip-flop 104C (collectively, “flip-flops 104”) that store and latch the command signal 108 based on a clk_0 signal, which may include an unshifted clock signal (e.g., 0°-shifted clock signal, in-phase clock signal) and that may be provided by the clock gating and generation circuitry 103. The clk_0 signal may be based on the internal clock signal LCLK of FIG. 1. For example, the clk_0 signal may be unshifted relative to the internal clock signal LCLK and have half a frequency of the internal clock signal LCLK. Further, the shifting stages 102 include a flip-flop 106A, a flip-flop 106B, and a flip-flop 106C (collectively, “flip-flops 106”) that store and latch the command signal based on a clk_180 signal. clk_180 signal is provided by the clock gating and generation circuitry 103 and may include a 180°-shifted version of the internal clock signal LCLK of FIG. 1. As illustrated, each of the flip-flops 104 and the flip-flops 106 may include an input pin D, an output pin Q, and a clock pin CK that may be used to store and latch the command signal. For example, an output pin Q of the flip-flop 104A is connected to an input pin D of the flip-flop 104B and, as such, the clk_0 signal may cause the command signal 108 to move (“shift”) from the flip-flop 104A to the flip-flop 104B. As the clk_0 and the clk_180 may correspond to every other cycle of the CLK, the flip-flops 104 may be used for one set (e.g., odd cycles or even) cycles while the flip-flops 106 are used for the other set of cycles. As such, each may be part of a respective odd or even pipeline for shifting commands based on the odd or even cycles.

The exit stage 114 may receive the command signal 108 from the shifting stage 102C. The exit stage 114 may include additional flip-flops, latches, inverters, OR gates, AND gates, or other logic gate circuitry that may manipulate the command signal 108 to produce an output command signal 116. For example, the exit stage 114 may shift and/or extend the command signal 108 to produce the output command signal 116, which may be better suited for use by other components than the command signal 108. However, to perform such shifts and extensions of the command signal 108, the exit stage may use different clock signals than those used by the shifting stages 102. In the illustrated example, the exit stage 114 may use a clk_90 signal and a clk_270 signal, which may include 90°-shifted version a 270°-shifted version of the internal clock signal LCLK of FIG. 1, respectively. For example, the exit stage 114 may use the clk_90 signal and the clk_270 signal to shift and/or extend the command signal 108 by 90° or 270° increments of an internal clock signal. For example, the clk_90 may correspond to an opposite edge (e.g., falling edge) of an edge (e.g., rising edge) of a same pulse the corresponds to the clk_0. Likewise, the clk_270 may correspond to the clk_180.

As mentioned, the clock gating and generation circuitry 103 may consume power to provide each of the illustrated clock signals. Further, the shifting stages 102 may be numerous and, because the shifting stages 102 may not use the clk_90 signal and the clk_270 signal, those clock signals may not be used by substantial portions of the command path circuitry 100. Thus, selectively generating the clk_90 signal and the clk_270 signal 120 may enable a reduction in power consumption by the clock gating and generation circuitry 103.

Accordingly, the clock gating and generation circuitry 103 may receive one or more busy signals 122 from one or more of the shifting stages 102 and, based on the busy signals 122, may determine whether to generate the clk_90 signal and the clk_270. The busy signals 122 may be generated by the shifting stages 102 based on a determination that flip-flops of the shifting stages 102 are busy in that they are storing and latching the command signal 108. Of note, the busy signals 122 may be generated by one or more final shifting stages (e.g., the shifting stage 102C) of the shifting stages 102 that are arranged prior (e.g., immediately prior) to the exit stage 114.

The final shifting stages may be arranged downstream of other shifting stages of command path circuitry, such that the final shifting stages receive a command signal after the other shifting stages and before the exit stage 114. As such, the busy signals 122 may indicate that the command signal 108 will soon arrive at the exit stage 114, and the clock gating and generation circuitry 103 may provide clk_90 signal and the clk_270 prior to use by the exit stage 114. It should be noted that, while the shifting stage 102C is illustrated as generating the busy signals 122, multiple shifting stages (e.g., a final 8 shifting stages) of the command path circuitry 100 may generate respective busy signals 122. This may allow the clock gating and generation circuitry 103 to provide the clk_90 signal and the clk_270 to the exit stage 114 with a suitable time buffer before the exit stage 114 uses such clock signals.

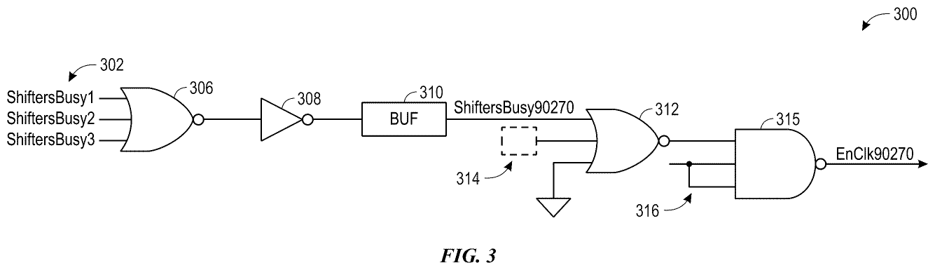

FIG. 3 is a block diagram of clock gating circuitry 300 that generates, based on one or more busy signals 302, an EnClk90270 signal as an enable signal for one or more clock signals. The clock gating circuitry 300 may be included as part of, or used in conjunction with, the clock gating and generation circuitry 103 of FIG. 2. For example, the one or more busy signals 302 may include a ShiftersBusy1 signal that may represent the one or more busy signals 122 of FIG. 2 from a first shifting stage 102.

In addition, the one or more busy signals 302 may include a ShiftersBusy2 signal that may be generated by a second shifting stage and a ShiftersBusy3 signal that may be generated by a third shifting stage (e.g., the shifting stage 102C). Each of the one or more busy signals 302 may be generated by final shifting stages. For example, the ShiftersBusy1 signal, the ShiftersBusy2 signal, and the ShiftersBusy3 signal may be generated by the final three shifting stages before an exit stage. Further, it should be noted that, while the one or more busy signals 302 are shown as three busy signals generated by three shifters, the one or more busy signals 302 may include any suitable number of signals generated by any suitable number of shifting stages. For example, the one or more busy signals 302 may include eight busy signals generated by the final eight shifting stages before an exit stage.

In the illustrated example, the clock gating circuitry 300 may receive the one or more busy signals 302 as input to a NOR gate 306. The output of the NOR gate 306 may be inverted by an inverter 308 and provided to buffer circuitry 310. The buffer circuitry 310 may buffer the inverted one or more busy signals 302 to generate a ShiftBusy90270 signal that indicates whether any of a number of final shifting stages of a command path and/or shifter are busy (e.g., storing and latching a command signal). As illustrated, the ShiftBusy90270 signal may be provided to a NOR gate 312. In some cases, the NOR gate 312 may receive, as input, one or more additional signals 314. The additional signals 314 may indicate whether other final shifting stages of other command paths and/or shifters are storing and latching a command signal. While not illustrated, the additional signals 314 may each be generated in a manner similar to that used to generate the ShiftBusy90270 signal. For example, other busy signals of other command paths and/or shifters may be provided to an additional NOR gate, an additional inverter, and additional buffer circuitry to generate the additional signals 314.

Moving on, the output of the NOR gate 312 may be provided to a NAND gate 315 to generate the EnClk90270 signal. In some cases, the NAND gate 315 may receive, as input, additional signals produced by additional logic 316. The additional logic 316 may further gate one or more clock signals, for instance. In the illustrated example, the EnClk90270 signal may indicate that one or more final shifting stages are busy. Returning to FIG. 2, the clock gating and generation circuitry 103 may provide, based on the EnClk90270 signal, the clk_90 signal and the clk_270 to the exit stage 114. As such, the clock gating and generation circuitry 103 may not generate and/or provide the clk_90 signal and the clk_270 until at least one of the final shifting stages (e.g., shifting stage 102C) are busy, which may be prior to the command signal 108 reaching the exit stage 114.

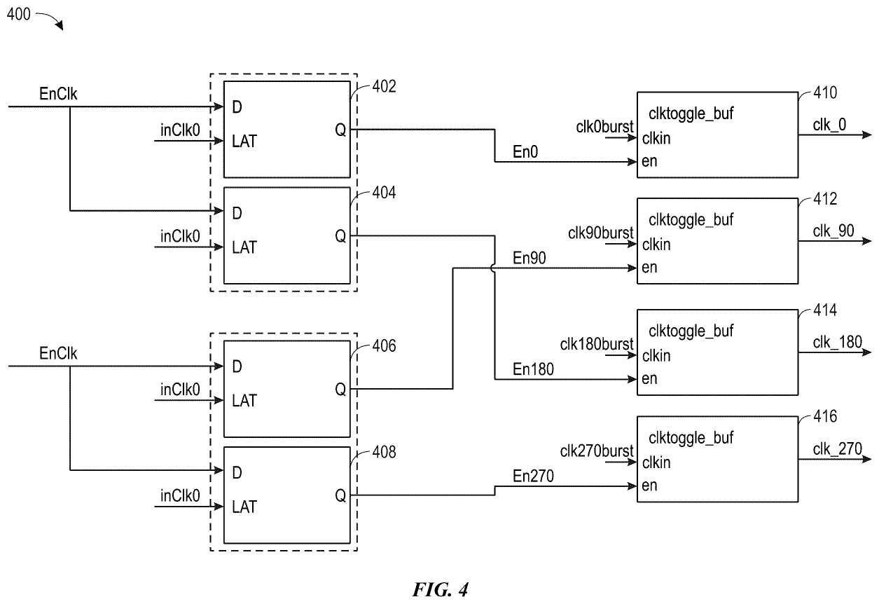

FIG. 4 is a block diagram of clock generation circuitry 400 that may selectively generate one or more clock signals, here illustrated as the clk_0 signal, the clk_90 signal, the clk_180 signal, and the clk_270 signal, based on one or more enable signals (e.g., an enable signal and an additional enable signal), here illustrated as the EnClk90270 signal and an EnClk signal. The clock generation circuitry 400 may be included as part of the clock gating and generation circuitry 103 of FIG. 2 and may be used in conjunction with the clock gating circuitry 300 of FIG. 3. For example, the clock gating circuitry 300 may generate the EnClk90270 signal based on one or more busy signals, and the clock generation circuitry 400 may generate one or more clock signals based on the EnClk90270 signal.

As illustrated, the clock generation circuitry 400 includes latches 402, 404, 406, and 408 that generate respective enable signals En0, En90, En180, and En270 based on the EnClk signal or the EnClk90270 signal. Each of the latches may include an input pin D, an output pin Q, and a latch pin LAT that may be used to store an input signal. For example, the latch 402 generates the En0 signal as the EnClk signal according to an inClk0 input clock signal, and the latch 404 generates the En180 signal as the EnClk signal according to an inClk180 input clock signal. Similarly, the latch 406 generates the En90 signal as the EnClk90270 signal according to the inClk90 input clock signal, and the latch 408 generates the En270 signal as the EnClk90270 signal according to the inClk270 input clock signal.

Each of the enable signals En0, En90, En180, and En270 may be provided to respective buffers 410, 412, 414, and 416. In the illustrated example, the buffer 410 may generate the clk_0 signal based on the En0 signal (e.g., when the En0 signal is high) and an input clk0burst signal derived from the CLK. Likewise, the buffer 412 may generate the clk_90 signal based on the En90 signal and an input clk90burst signal derived from the CLK, the buffer 414 may generate the clk_180 signal based on the En180 signal and an input clk180burst signal derived from the CLK, and the buffer 416 may generate the clk_270 signal based on the En270 signal and an input clk270burst signal derived from the CLK. As such, each of the clock signals clk_0, clk_90, clk_180, and clk_270 may be generated based on separate enable signals. Further, the enable signals En0 and En180 may be generated based on the EnClk signal, while the enable signals En90 and En270 may be generated based on the EnClk90270 signal. Thus, the clk_90 and the clock_270 may be generated separately from the clk_0 and clk_180 signals, which may be advantageous, as each clock signal may be used at different times. For example, the clk_0 and clk_180 signals may be used for corresponding portions of the command path (e.g., one or more shifting stages of a respective pipeline) while the clk_90 and clk_270 signals are used for an exit stage of the command path. Accordingly, the EnClk signal may be high (e.g., asserted) during a first portion of the command path, and the EnClk90270 signal may be low during the first portion of the command path and set high prior to operation of the exit stage.

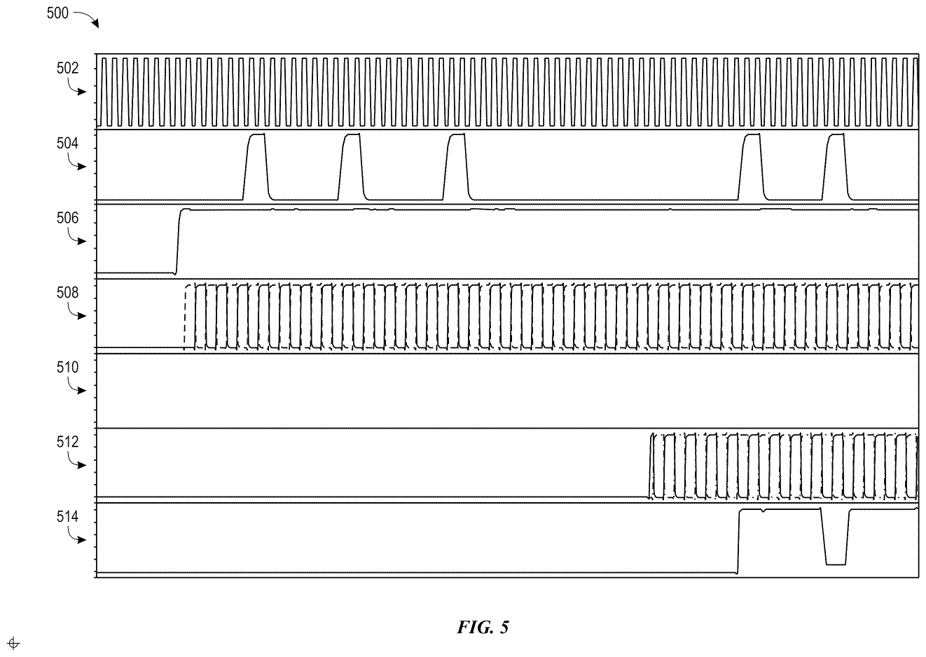

FIG. 5 is a timing diagram 500 that includes example waveforms of signals used by the clock gating and generation circuitry 103 to selectively provide one or more clock signals. The illustrated timing diagram 500 includes an internal clock signal 502, such as the internal clock signal LCLK of FIG. 1. The timing diagram 500 also includes a waveform of a command signal 504, which may represent the command signal 108 of FIG. 2. This command signal 504 may include a read command signal or write command signal, for instance. Additionally, the timing diagram 500 includes a waveform of an enable signal 506 for a first set of phase-shifted clock signals. The enable signal 506 may represent the EnClk signal that is used to generate the clk_0 signal and the clk_180 signals, for instance. The timing diagram 500 also includes a waveform of the first set of phase-shifted clock signals 508, such as the clk_0 signal or the clk_180 signals. As illustrated, the first set of phase-shifted clock signals 508 is generated after the enable signal 506 is set high. Further, as shown, the first set of phase-shifted clock signals 508 may be generated based on the internal clock signal 502. For example, the first set of phase-shifted clock signals 508 may have a frequency half that of the internal clock signal 502 since the phase-shifted clock signals 508 may correspond to alternating cycles of the internal clock signal 502.

The timing diagram also includes a waveform of an enable signal 510 for a second set of phase-shifted clock signals. The enable signal 510 may represent the EnClk90270 signal that is used to generate the clk_90 signal and the clk_270 signal, for example. Further, the timing diagram 500 includes a waveform of the second set of phase-shifted clock signals 512, which may represent the clk_90 signal and the clk_270 signal. The second set of phase-shifted clock signals 512 may be generated and used to generate an output command signal 514. For example, the clock gating and generation circuitry 103 may provide the second set of phase-shifted clock signals 512 to the exit stage 114, and the exit stage may generate the output command signal 514 based on the second set of phase-shifted clock signals 512.

Like the first set of phase-shifted clock signals 508, the second set of phase-shifted clock signals 512 may be generated based on the internal clock signal 502 (e.g., may have a frequency half that of the internal clock signal 502). However, because the enable signal 510 is set high (e.g., asserted) after the enable signal 506 is set high, the second set of phase-shifted clock signals 512 is generated later than the first set of phase-shifted clock signals 508 is generated. As such, power consumption associated with generating the second set of phase-shifted clock signals 512 may be reduced.

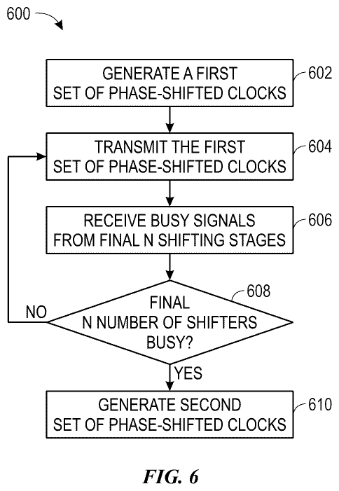

FIG. 6 is a flow chart of a method 600 for selectively providing one or more clock signals (e.g., the clk_90 signal and the clk_270 signal) to one or more stages of command path circuitry (e.g., the exit stage 114 of the command path circuitry 100) that may be performed by the clock gating and generation circuitry 103. In block 602, the method 600 may begin with generating a first set of phase shifted clock signals, such as the clk_0 signal and the clk_180 signal. As mentioned, the clk_0 signal may include a divided and unshifted clock signal (e.g., 0°-shifted clock signal), such as the internal clock signal LCLK of FIG. 1, and the clk_180 signal may include a divided and 180°-shifted version of the internal clock signal LCLK of FIG. 1. Block 602 may include, for example, setting the EnClk high such that the clk_0 and clk_180 are generated (e.g., by the clock generation circuitry 400). In block 604, the method may continue with transmitting the first set of phase-shifted clocks to the shifting stages 102 of the command path circuitry 100. The clk_0 and clk_180 signals may be provided to the flip-flops 104 and 106 of the shifting stages 102 such that the command signal 108 shifts according to the clk_0 and/or the clk_180, for instance.

In block 606, the clock gating and generation circuitry 103 may receive the one or more busy signals 122 from one or more final shifting stages of the shifting stages 102. The busy signals 122 may be generated by the shifting stages 102 based on a determination that flip-flops of the shifting stages 102 are busy in that they are storing and latching the command signal 108. As described herein, the busy signals 122 may be generated by one or more final shifting stages of the shifting stages that are arranged prior (e.g., immediately prior) to the exit stage. As such, the busy signals 122 may indicate that the command signal 108 will soon (e.g., within a threshold of time) arrive at the exit stage 114. Additionally, in some cases, the clock gating and generation circuitry 103 may receive busy signals from final shifting stages of multiple command path circuitries and/or shifters. The threshold may be long enough to enable the clocks, settle the clocks, and deliver the clocks to the exit stage 114.

In block 608, the clock gating and generation circuitry 103 may determine whether the final shifting stages are busy (e.g., storing and latching the command signal 108). Block 608 may be performed by the clock gating circuitry 300, for instance. Determining whether the final shifting stages are busy may include the clock gating circuitry 300 receiving, as input to the NOR gate 306, the one or more busy signals 302, using the inverter 308 to invert the output of the NOR gate 306, and buffering the output of the inverter 308 to produce the ShiftBusy90270 signal. Determining whether the final shifting stages are busy may also include providing the ShiftBusy90270 signal to the NOR gate 312 along with additional signals 314. The additional signals 314 may indicate whether other final shifting stages of other command paths and/or shifters are storing and latching a command signal. Further, block 608 may include providing the output of the NOR gate 312 to the NAND gate 315 to produce the EnClk90270 signal. In an example, the EnClk90270 signal is high if the final shifting stages are busy and low if the final shifting stages are not busy. If the final shifting stages are not busy, the clock gating and generation circuitry 103 may continue to transmit the clk_0 and clk_180 signals to the shifting stages 102 in block 604. In such situations, the clock gating and generation circuitry 103 may suppress generation and/or delivery of some clocks, such as the clk_90 and the clk_270.

If, however, the final shifting stages are busy, in block 610, the clock gating and generation circuitry 103 may generate a second set of phase-shifted clock signals, such as the clk_90 signal and the clk_270 signal. As mentioned, the clk_90 signal may include a divided and 90°-shifted version of the internal clock signal LCLK of FIG. 1, and the clk_270 signal may include a divided and 270°-shifted version of the internal clock signal LCLK. Block 610 may include, for example, using the clock gating circuitry 300 to set the EnClk90270 high such that the clk_90 and clk_270 are generated (e.g., by the clock generation circuitry 400). Once generated, the clock gating and generation circuitry 103 may transmit the second set of phase-shifted clocks to, for example, the exit stage 114. As mentioned, the exit stage 114 may use the clk_90 signal and the clk_270 signal to shift, extend, or otherwise manipulate the command signal 108 in 90° or 270° increments.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. A memory device, comprising:
command path circuitry comprising:
shifting circuitry configured to shift a command signal, and comprising one or more final shifters, and
clock gating and generation circuitry configured to:
generate a first set of phase-shifted clock signals;
transmit the first set of phase shifted clock signals to the shifting circuitry;
receive one or more busy signals from the shifting circuitry;
determine, based on the one or more busy signals, that the one or more final shifters are storing the command signal based on at least one of the first set of phase-shifted clock signals; and
generate, based on the determination, a second set of phase-shifted clock signals.

2. The memory device of claim 1, wherein the command path circuitry comprises exit stage circuitry configured to:
receive the command signal from the shifting circuitry; and
output an output command signal based on the command signal.

3. The memory device of claim 2, wherein the clock gating and generation circuitry is configured to transmit the second set of phase-shifted clock signals to the exit stage circuitry, and wherein the exit stage circuitry is configured to output the output command signal based on the second set of phase-shifted clock signals.

4. The memory device of claim 2, wherein the exit stage circuitry is configured to receive the command signal from the one or more final shifters of the shifting circuitry.

5. The memory device of claim 1, wherein the one or more busy signals comprise respective busy signals from each of the one or more final shifters of the shifting circuitry.

6. The memory device of claim 5, wherein to determine, based on the one or more busy signals, that the one or more final shifters of the shifting circuitry are storing the command signal, the clock gating and generation circuitry is configured to:
receive the respective busy signals; and
generate an enable signal based on the respective busy signals.

7. The memory device of claim 6, wherein to generate the clock gating and generation circuitry is configured to generate the second set of phase-shifted clock signals based on the enable signal.

8. The memory device of claim 7, wherein the clock gating and generation circuitry is configured to generate the first set of phase-shifted clock signals based on an additional enable signal.

9. The memory device of claim 1, wherein the command path circuitry comprises one or more first shifters, and wherein each of the one or more first shifters and the one or more final shifters comprise one or more flip-flops configured to store and shift the command signal, and wherein a first shifter of the one or more final shifters is configured to receive the command signal from a first shifter of the one or more first shifters.

10. The memory device of claim 1, wherein the clock gating and generation circuitry configured to not generate the second set of phase-shifted clock signals in response to determining, based on the one or more busy signals, that the one or more final shifters are not storing the command signal based on at least one of the first set of phase-shifted clock signals.

11. A method, comprising:
providing a first set of phase-shifted clock signals to command path circuitry of a memory device;
receiving one or more busy signals from the command path circuitry;
asserting, based on at least one of the one or more busy signals being asserted, an enable signal for a second set of phase-shifted clock signals;
suppressing generation of the second set of phase-shifted clock signals based on the enable signal not being asserted;
generating the second set of phase-shifted clock signals based on the enable signal being asserted; and
transmitting the second set of phase-shifted clock signals to exit stage circuitry of the command path circuitry.

12. The method of claim 11, wherein the command path circuitry comprises shifting circuitry configured to shift a command signal based on the first set of phase-shifted clock signals.

13. The method of claim 12, wherein the shifting circuitry comprises first shifters and second shifters, the first shifters configured to shift the command signal to the second shifters, and wherein the one or more busy signals are received from the second shifters.

14. The method of claim 13, wherein the exit stage circuitry is configured to receive the command signal from the second shifters.

15. The method of claim 11, comprising generating the first set of phase-shifted clock signals based on an additional enable signal.

16. The method of claim 11, wherein the first set of phase-shifted clock signals and the second set of phase-shifted clock signals are each generated based on an internal clock signal.

17. A memory device, comprising:
first command path circuitry configured to shift a command signal based on a clock signal of a first set of clock signals;
second command path circuitry configured to:
receive the command signal from the first command path circuitry;
shift the command signal based on a second set of clock signals;
clock gating circuitry configured to:
receive one or more busy signals from the first command path circuitry;
generate an enable signal based on the one or more busy signals;
clock generation circuitry configured to:
receive the enable signal; and
generate, based on the enable signal, the second set of clock signals.

18. The memory device of claim 17, wherein the clock generation circuitry is configured to:
generate the first set of clock signals based on an additional enable signal;
transmit the first set of clock signals to the first command path circuitry;
after transmitting the first set of clock signals to the first command path circuitry, generate the second set of clock signals; and
transmit the second set of clock signals to the second command path circuitry.

19. The memory device of claim 17, wherein the first set of clock signals comprises a first clock signal that is in-phase with a clock signal of the memory device, a second clock signal that is phase-shifted by 180 degrees of the clock signal of the memory device, or both.

20. The memory device of claim 17, wherein the second set of phase-shifted clock signals comprises a third clock signal that is phase-shifted by 90 degrees of a clock signal of the memory device, a fourth clock signal that is phase-shifted by 270 degrees of the clock signal of the memory device, or both.
